(19) United States
(12) Patent Application Publication
(10) Pub. No.: US 2019/0019781 A1
(43) Pub. Date: Jan. 17, 2019

(54) TRANSPARENT ACTIVE MATRIX DISPLAY COMPRISING EMITTING PIXELS WITH COLORED LIGHT-EMITTING DIODES

(71) Applicant: THALES, Courbevoie (FR)

(72) Inventor: Hugues LEBRUN, COUBLEVIE (FR)

(21) Appl. No.: 16/034,306

(22) Filed: Jul. 12, 2018

(30) Foreign Application Priority Data
Jul. 13, 2017 (FR) 1700754

(51) Int. Cl. H01L 25/075; H01L 27/12; H01L 33/62

(52) U.S. Cl. CPC H01L 25/0753; H01L 33/62; H01L 27/1214

(57) ABSTRACT

Displays are provided and including a transparent plate and a matrix array of pixels composed of light-emitted diodes arranged on the plate. In the display, each pixel is an electronic component including a triplet of three light-emitting diodes emitting in three different spectra and four electrical contacts, each light-emitting diode having a dedicated electrical control contact, the three diodes having an electrical contact that is common to the three light-emitting diodes, the area occupied by the matrix array of pixels being an order of magnitude smaller than that of the transparent substrate. In a first variant, the pixel includes six diodes and in a second variant, the pixel includes twelve diodes. The placement of the pixels is thus facilitated. The control electronics are adapted so as to decrease the number of control lines and columns. The transparency of the display is thus increased.

### CROSS-REFERENCE TO RELATED APPLICATIONS

This application claims priority to foreign French patent application No. FR 1700754, filed on Jul. 13, 2017, the disclosure of which is incorporated by reference in its entirety.

### FIELD OF THE INVENTION

The field of the invention is that of transparent viewing devices allowing an image or information to be displayed as if superimposed on the outside. They may be used in particular in the automotive or aeronautical fields.

### BACKGROUND

A transparent display includes a matrix array of emitting colour pixels addressed by a set of conductive lines and columns. Each intersection of lines and of columns includes a pixel and its addressing electronics, as can be seen in FIG. 1.

For the screen to retain a good degree of transparency, it is enough for the assembly of lines, columns, pixels and associated electronics to occupy only a small portion of the screen.

The emitting pixels may be light-emitting diodes, or LEDs, which present a number of advantages. Worth mentioning in particular are their substantial emitting power, small footprint and high reliability.

In this case, the control or addressing electronics include multiple transistors produced in thin layers. The at least one that is connected to a line and a column stores the video information. A second transistor that is connected to a power supply and to the light-emitting diode controls the current through said diode.

This transistor may be positioned below the diode so as to decrease the area occupied by the matrix array of diodes.

The simplest way to produce this transparent LED screen is shown in FIG. 1, which shows a partial view of a screen placed on a transparent substrate 1. Each intersection of addressing lines 2 and columns 3 includes a single light-emitting diode. To produce a colour display, three different types of diodes 4, 5 and 6 are used, each emitting in the red, blue and green, respectively.

This type of screen has two significant drawbacks. If it is desired to produce a “full-HD” screen, this screen must include 1080 lines and 1920 columns. Each colour pixel then includes three elementary light-emitting diodes. Thus, the screen includes more than 6 million light-emitting diodes. If the diode pick-and-place machine is capable of placing 60 000 components an hour, it therefore needs more than 100 pick-and-place hours to produce the transparent display.

Furthermore, the components to be handled by the pick-and-place method are very small in size. Typically, the dimensions of a light-emitting diode are in the region of 100 microns. These components are therefore difficult to handle and to position accurately over large areas. Furthermore, they are liable to move during the thermalization process required to set the bonding compound, which also provides electrical conduction.

The transparent display according to the invention goes a long way towards overcoming the preceding drawbacks. Specifically, the light-emitting diodes are grouped together into at least RGB (red-green-blue) triplets, each triplet constituting a colour pixel. Thus, the number of components to be placed is decreased, the size thereof is increased and the number of addressing lines and columns is decreased. The production time of the display is shorter, and it is simpler to produce, more reliable and more transparent.

### SUMMARY OF THE INVENTION

More specifically, one subject of the invention is a display including a transparent plate and a matrix array of pixels composed of light-emitting diodes arranged on said plate, characterized in that each pixel is an electronic component including a triplet of three light-emitting diodes emitting in three different spectra and four electrical contacts, the three light-emitting diodes being produced on one and the same substrate, each light-emitting diode having a dedicated electrical control contact, the three diodes having an electrical contact that is common to said three light-emitting diodes, the area occupied by the matrix array of pixels being an order of magnitude smaller than that of the transparent plate.

Advantageously, each electronic component includes two triplets of three light-emitting diodes and seven electrical contacts, each light-emitting diode having a dedicated electrical control contact, the two triplets of three light-emitting diodes being produced on one and the same substrate, the six diodes having an electrical contact that is common to said six light-emitting diodes, the area occupied by the matrix array of pixels being an order of magnitude smaller than that of the transparent plate.

Advantageously, each electronic component includes four triplets of three light-emitting diodes and thirteen electrical contacts, the four triplets of three light-emitting diodes being produced on one and the same substrate, each light-emitting diode having a dedicated electrical control contact, the twelve diodes having an electrical contact that is common to said twelve light-emitting diodes, the area occupied by the matrix array of pixels being an order of magnitude smaller than that of the transparent plate.

Advantageously, the substrate is made of sapphire, silicon carbide or silicon.

Advantageously, the transparent plate including a set of control lines and a set of control columns, for each triplet of diodes, the first electrical control contact is linked to a first line, the second electrical control contact is linked to a second line, the third electrical control contact is linked to the first line and to the second line by means of a sample-and-hold circuit.

Advantageously, the transparent plate including a set of control lines and a set of control columns,

The first triplet of diodes is linked both to a first control column, a second control column and a third control column and to a first control line;

The second triplet of diodes is linked both to said first control column, said second control column and said third control column and to a second control line;

The third triplet of diodes is linked both to said first control column, said second control column and said third control column and to said first control line and a third control line by means of a first triplet of sample-and-hold circuits;

The fourth triplet of diodes is linked both to said first control column, said second control column and said third control column and to said second control line and said third control line by means of a second triplet of sample-and-hold circuits.

Advantageously, each sample-and-hold circuit is controlled by the third line and by one of the three control columns.

Advantageously, the area of the placement surface of the electronic component is about 300 microns by 300 microns in the case of a triplet of diodes, about 300 microns by 600 microns in the case of two triplets and 600 microns by 600 microns in the case of four triplets of light-emitting diodes.

The invention also relates to a process for producing a display such as defined above, characterized in that the process includes a step of bonding the electronic components to bonding pads, the adhesive being conductive, isotropic and of solder paste-type.

Advantageously, in one variant embodiment, the bonding step is carried out by means of an anisotropic conductive film-type bonding film, the adhesive being anisotropic, composed of an insulating medium including conductive microbeads.

### BRIEF DESCRIPTION OF THE DRAWINGS

The invention will be better understood and other advantages will become apparent on reading the following description, which is given by way of nonlimiting example, and by virtue of the appended figures in which:

FIG. 1, mentioned above, shows a transparent screen according to the prior art;

FIG. 2 shows a triplet of light-emitting diodes according to the invention;

FIG. 3 shows two triplets of light-emitting diodes according to the invention;

FIG. 4 shows four triplets of light-emitting diodes according to the invention;

FIG. 5 shows the placement of the components with four triplets of diodes on a transparent screen;

FIG. 6 shows the electrical control circuit of a light-emitting diode;

FIG. 7 shows a variant of the electrical control circuit of FIG. 6;

FIG. 8 shows the electrical control circuit of a triplet of light-emitting diodes according to the invention;

FIG. 9 shows the electrical control circuit of a component including four triplets of light-emitting diodes according to the invention;

FIG. 10 shows a variant of the electrical control circuit of FIG. 9;

FIG. 11 shows the mounting of the LED components according to the invention on their transparent substrate;

FIG. 12 shows a variant of the mounting of the components of FIG. 11.

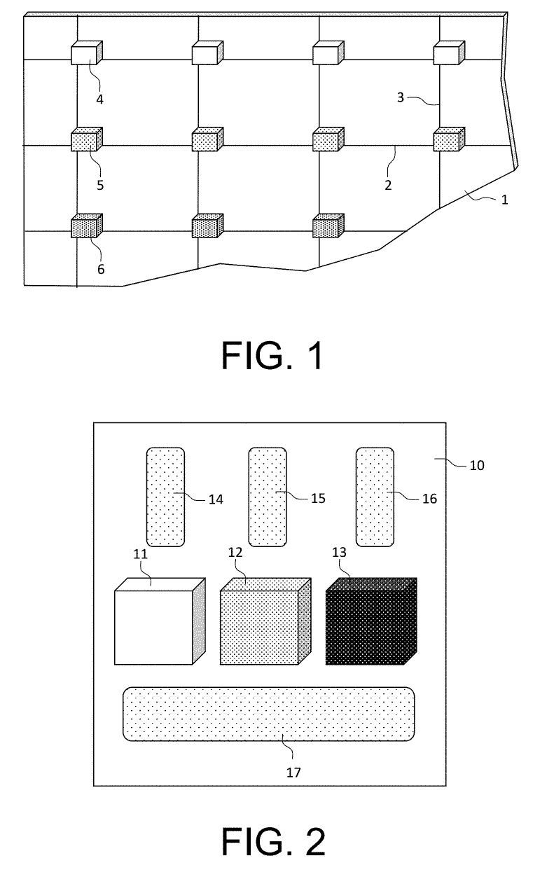

### DETAILED DESCRIPTION

FIG. 2 shows a triplet of light-emitting diodes according to the invention. It takes the form of an electronic component 10. This component includes three light-emitting diodes 11, 12 and 13, emitting in the red, the green and the blue, respectively. These light-emitting diodes may, by way of example, inherently emit the various colours or emit the various colours by conversion, either via phosphors or via quantum dots. In particular, the colour blue may be obtained by direct emission or result from a conversion via a suitable phosphor or quantum dots from ultraviolet emission radiation.

The three diodes are produced on the same substrate. By way of examples, this substrate may be made of sapphire, silicon carbide or silicon.

In FIG. 2, by way of nonlimiting example, these light-emitting diodes are aligned. This component also includes four electrical contacts 14, 15, 16 and 17. Each light-emitting diode has a dedicated electrical control contact, the three diodes having a common electrical power supply contact 17. Thus, with respect to three individual diodes, the component includes two fewer contacts. The size of each diode is about 80 μm×120 μm. The dimensions of each contact, or bump, are about 30 μm×80 μm. The size of the individual component is about 300 μm×300 μm. This size is close to the industry standards for placing electronic components and allows the pick-and-place operation to be divided by three while making it more straightforward.

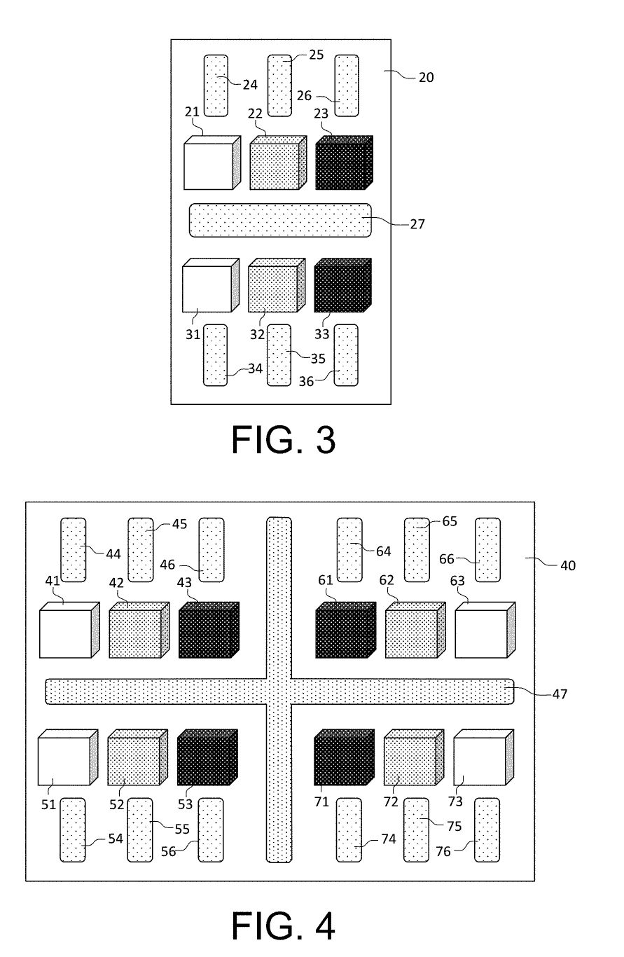

FIG. 3 shows a first variant embodiment of this component. The electronic component 20 includes two triplets of three light-emitting diodes 21, 22 and 23; and 31, 32 and 33 and seven electrical contacts 24-26, 34-36 and 27, each light-emitting diode having a dedicated electrical control contact, the six diodes having an electrical contact 27 that is common to the six light-emitting diodes. The geometric placement of the light-emitting diodes and of the electrical contacts of FIG. 3 is given by way of example. Thus, with respect to six individual diodes, the component includes five fewer contacts. The size of the individual component is about 600 μm×300 μm. The preceding pick-and-place time is now divided by two.

FIG. 4 shows a second variant embodiment of this component. The electronic component 40 includes four triplets of three light-emitting diodes 41-43, 51-53, 61-63 and 71-73 and 13 electrical contacts 44-46, 54-56, 64-66, 74-76 and 47, each light-emitting diode having a dedicated electrical control contact, the twelve diodes having an electrical contact 47 that is common to the twelve light-emitting diodes. The geometric placement of the light-emitting diodes and of the electrical contacts of FIG. 4 is given by way of example. The size of the individual component is about 600 μm×600 μm. Thus, with respect to twelve individual diodes, the component includes eleven fewer contacts. This type of component allows the pick-and-place time of a colour screen to be divided by twelve. For a full-HD screen, 518 400 elementary components must then be placed, which can be achieved in 8.64 hours on a fast pick-and-place machine placing 60 000 components per hour.

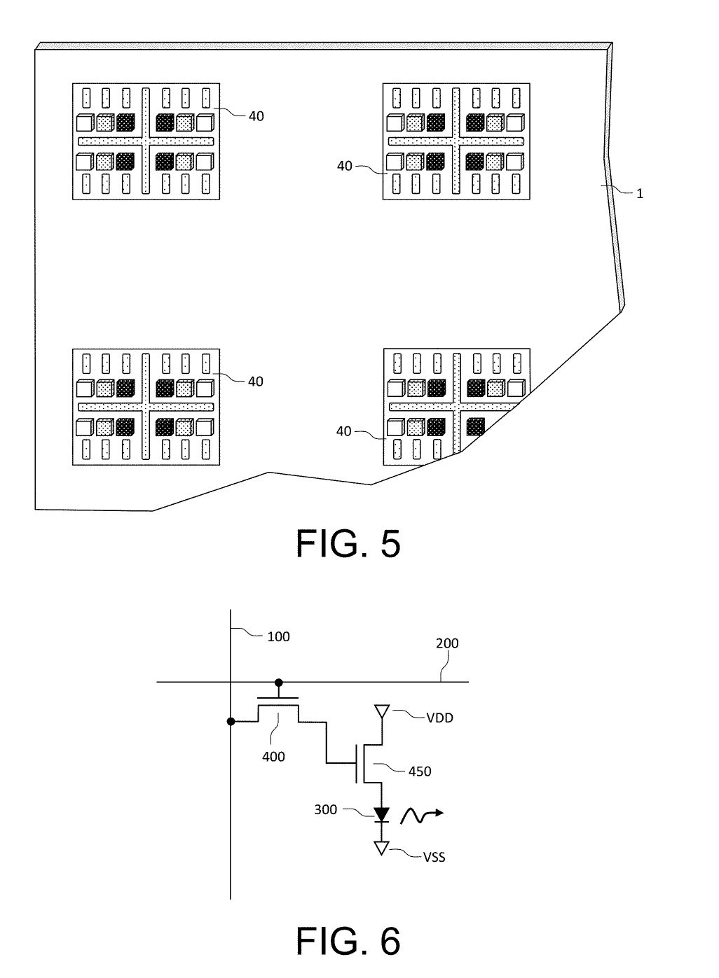

As can be seen in FIG. 5, which shows a partial view of a screen according to the invention, this type of component 40 makes it possible to produce screens of large size with a decrease in the area of light-emitting diodes on a sapphire substrate that is typically of the order of 10% of the area of the glass of the active matrix 1. In the case of FIG. 5, the components are implanted every millimetre.

FIG. 6 shows the control electronics of a light-emitting diode 300. This is placed on the transparent plate in the vicinity of the intersections between the various lines 200 and columns 100.

It includes two electric power supply planes referenced, as is conventional, “VDD” and “VSS” on FIG. 6 and two control transistors 400 and 450. The first transistor 400 is connected to the control column 100 and to the control line 200. It drives the transistor 450, which controls the light-emitting diode 300.

The LED control device may be produced using a larger number of transistors to improve the performance of the display. For example:

transistors may be added to compensate for variations in the electrical characteristics between the diodes or between the transistors so as to compensate for the threshold voltages;

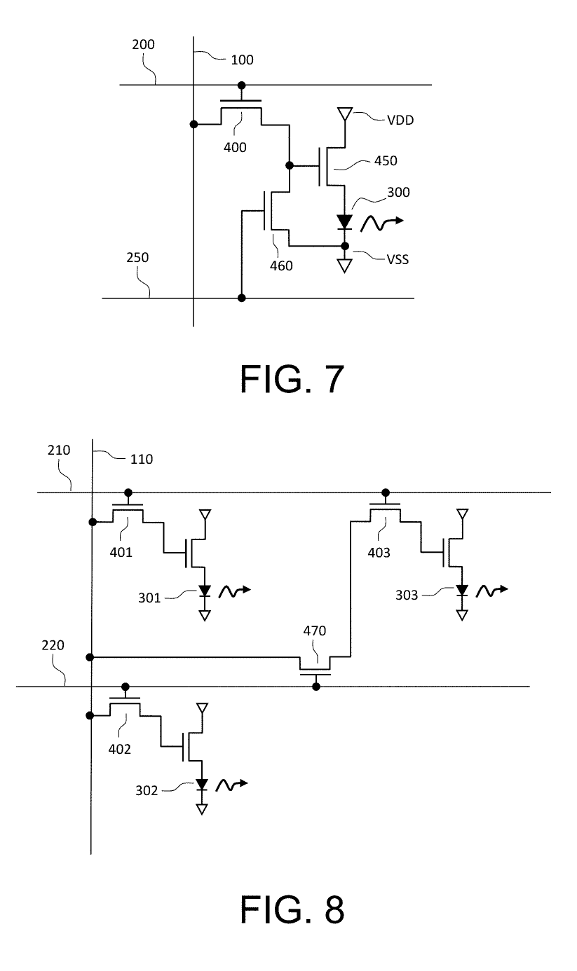

a “RESET” transistor 460 may be added, such as shown in FIG. 7. The references used in this figure are the same as in the preceding figure. This transistor is connected to a “reset” line 250, to the transistor 450 and to the power supply plane VSS. It allows the diode activation time to be decreased, so as to allow a decrease in the emission of light when the display is used in a dark environment.

To control a triplet of light-emitting diodes, one control line and one control column may be assigned to each light-emitting diode, giving a total of six conductive control lines. However, in the case of a triplet of diodes according to the invention, control may be carried out by means of a single control line and three control columns, giving a total of only four conductive control lines.

The number of conductive lines required for driving a triplet of diodes according to the invention may be further decreased, as can be seen in the circuit diagram of FIG. 8. In this case, an RGB LED triplet may be controlled by only two lines 210 and 220 and a single column 110, giving three conductive lines.

The electronic device is as follows. The first diode 301 is controlled, as is conventional, by electronics with two transistors such as described in FIG. 6, the transistor 401 being linked to the line 210 and to the column 110. Similarly, the second diode 302 is controlled, as is conventional, by electronics with two transistors, the transistor 402 being linked to the line 220 and to the column 110. The third diode 303 also includes control electronics with two transistors but the transistor 403 is linked to a transistor 470 controlled by the column 110 and the line 220. Thus, by means of the transistors 402 and 470, the diode is connected to the control column 110 and to the two control lines 210 and 220.

The operation of the triplet is as follows. The line 210 activates the diode 301, then the line 220 activates the diode 302. Lastly, the simultaneous action of the lines 210 and 220 activates the diode 303. The column 110 holds the information corresponding to the diode 303 during the simultaneous activation of the two lines 210 and 220, then the information corresponding to the diode 301 during the activation of the first line 210 only and the information corresponding to the diode 302 during the activation of the line 220 only.

The decrease in the number of lines and of columns allows the metal area of the active matrix to be decreased and hence promotes the transparency of the display.

The preceding principles may be put to use in supplying power to an electronic component including four triplets of three diodes. In this case, the power supply circuit comprises two lines and four columns.

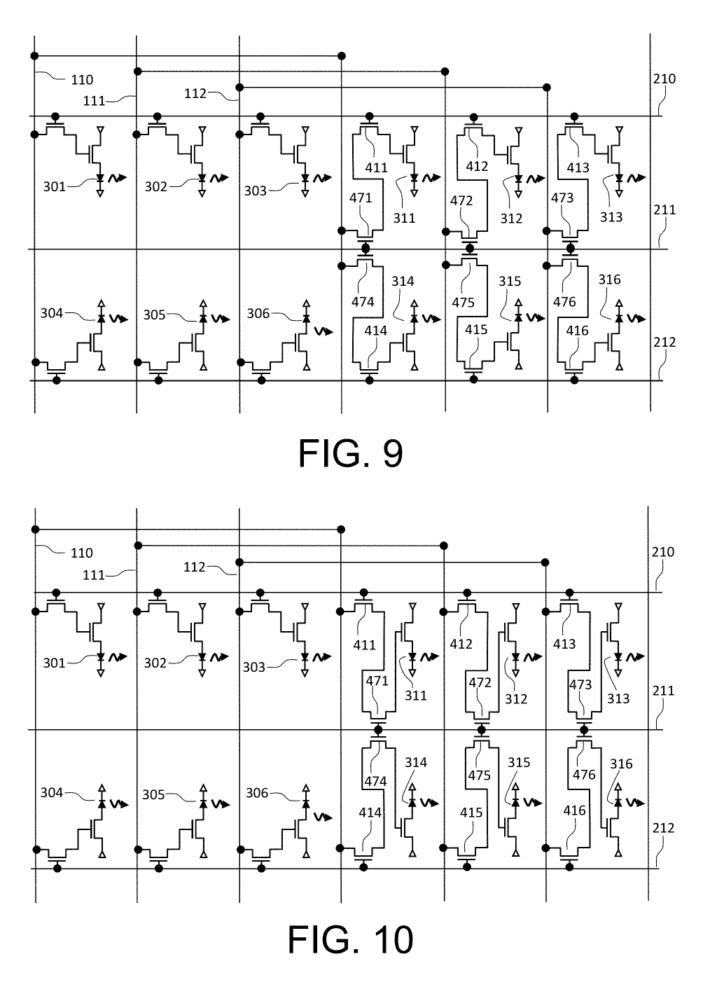

In one variant embodiment, it is possible to supply power to a component including twelve diodes by means of three control lines and three control columns. The diagram of the corresponding electronic control circuit is shown in FIG. 9. It includes three lines 210, 211 and 212 and three columns 110, 111 and 112.

A first triplet of diodes 301, 302 and 303 is linked both to the first control column 110, the second control column 111 and the third control column 112, and to the first control line 210.

The second triplet of diodes 304, 305 and 306 is linked both to the first control column 110, the second control column 111 and the third control column 112, and to the second control line 212.

The third triplet of diodes 311, 312 and 313 is linked both to the first control column 110, the second control column 111 and the third control column 112, and to the first control line 210 and to the third control line 211 by means of a first triplet of sample-and-hold circuits 471, 472 and 473. Each sample-and-hold circuit is linked to a column, to the line 211 and to the transistor that drives the corresponding diode. Thus, the sample-and-hold circuit 471 is linked to the column 110, to the line 211 and to the transistor 411 that drives the diode 311.

The fourth triplet of diodes 314, 315 and 316 is linked both to the first control column 110, the second control column 111 and the third control column 112, and to the second control line 212 and the third control line 212 by means of a second triplet of sample-and-hold circuits 474, 475 and 476.

The diodes 311 to 316 including a sample-and-hold circuit are systematically activated before the diodes 301 to 306. The lines 210 and 211 are activated simultaneously before the activation of the line 210 alone and, similarly, the lines 211 and 212 are activated simultaneously before the activation of the line 212 alone.

In one variant embodiment shown in FIG. 10 of the electronic addressing circuit of FIG. 9, the sample-and-hold circuit transistors 471 to 476 are connected differently. Each sample-and-hold circuit is linked to a first control transistor, to the line 211 and to the second transistor that drives the corresponding diode. Thus, the sample-and-hold circuit 471 is linked to the transistor 411, to the line 211 and to the second transistor that drives the diode 311.

In all cases of controlling the diodes with two transistors in series in the sample-and-hold circuits, the transistor that is electrically closest to the column must be turned off last so as to decrease emitting diode-line coupling.

The portions of the electrodes of the transparent substrate that are positioned below the components may be reflective so as to promote the emission of the light emitted by the light-emitting diodes towards the user. It is preferable for the area of the control electronics of the components according to the invention to be entirely masked by the component itself so as to optimize the transmission of the display.

The components according to the invention may be placed on the transparent plate including the control lines and columns and the associated control electronics by means of a conductive adhesive.

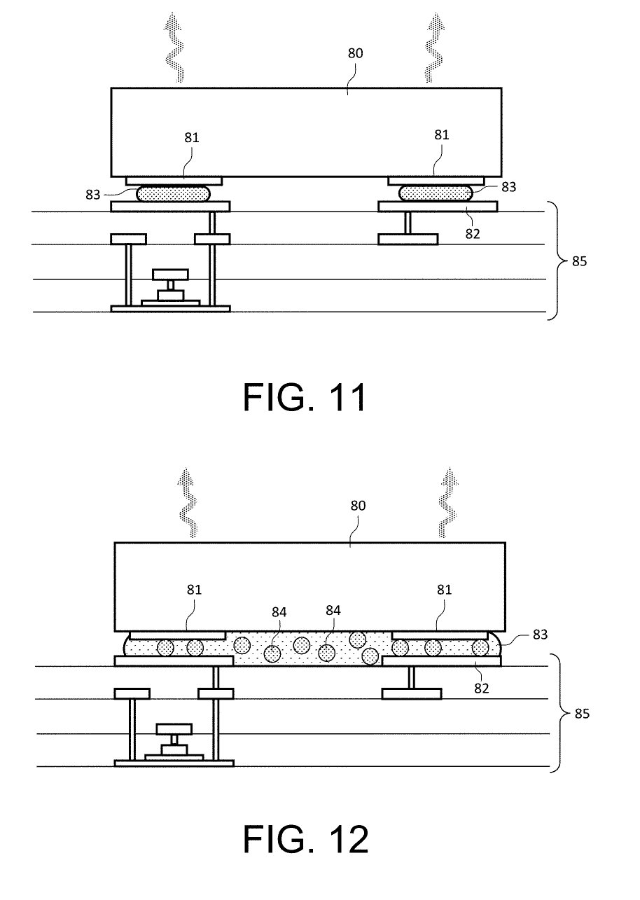

In a first embodiment shown in FIG. 11, the contacts 81 of the component 80 are attached to the contacts 82 of the control electronics 85 by means of pads 83 of conductive adhesive. The control electronics are shown in a simplified manner in this figure and the next. In FIG. 11 and the next, the light-emitting diodes are not shown. This conductive adhesive is isotropic. It is of solder paste or equivalent type. By way of example, it is placed on the contacts of the active matrix by screen-printing and then heat-cured.

In a second embodiment shown in FIG. 12, the contacts 81 of the component 80 are attached to the contacts 82 of the control electronics 85 by means of a single pad 83 of conductive adhesive. This conductive adhesive is anisotropic. It contains an insulating medium including disjunct conductive elements 84. These elements may be microbeads coated with gold or with another metal. As above, each pad may be deposited by screen-printing. It is also possible to use an adhesive strip containing the metal-coated microbeads, the strip being of anisotropic conductive film (ACF) type. This adhesive is then strip-laminated onto the glass. These various adhesives are heat-, ultraviolet- or pressure-cured.

These mounting methods may be applied to components including a triplet of light-emitting diodes or to two triplets or four triplets. Furthermore, it is preferable for the material used for the bonding to be opaque so as to decrease the amount of light that is propagated towards the control transistors, the operation of which could be disrupted by this light.

1. A display including a transparent plate and a matrix array of pixels composed of light-emitting diodes arranged on said plate, wherein each pixel is an electronic component including a triplet of three light-emitting diodes emitting in three different spectra and four electrical contacts, the three light-emitting diodes being produced on one and the same substrate, each light-emitting diode having a dedicated electrical control contact, the three diodes having an electrical contact that is common to said three light-emitting diodes, the area occupied by the matrix array of pixels being an order of magnitude smaller than that of the transparent plate.

2. The display according to claim 1, wherein each electronic component includes two triplets of three light-emitting diodes and seven electrical contacts, the two triplets of three light-emitting diodes being produced on one and the same substrate, each light-emitting diode having a dedicated electrical control contact, the six diodes having an electrical contact that is common to said six light-emitting diodes, the area occupied by the matrix array of pixels being an order of magnitude smaller than that of the transparent plate.

3. The display according to claim 2, wherein each electronic component includes four triplets of three light-emitting diodes and thirteen electrical contacts, the four triplets of three light-emitting diodes being produced on one and the same substrate, each light-emitting diode having a dedicated electrical control contact, the twelve diodes having an electrical contact that is common to said twelve light-emitting diodes, the area occupied by the matrix array of pixels being an order of magnitude smaller than that of the transparent plate.

4. The display according to claim 1, wherein the substrate is made of sapphire, silicon carbide or silicon.

5. The display according to claim 1, wherein the transparent plate including a set of control lines and a set of control columns, for each triplet of diodes, the first electrical control contact is linked to a first line, the second electrical control contact is linked to a second line, the third electrical control contact is linked to the first line and to the second line by means of a sample-and-hold circuit.

6. The display according to claim 3, wherein the transparent plate including a set of control lines and a set of control columns,
the first triplet of diodes is linked both to a first control column, a second control column and a third control column and to a first control line;
the second triplet of diodes is linked both to said first control column, said second control column and said third control column and to a second control line;
the third triplet of diodes is linked both to said first control column, said second control column and said third control column and said first control line and to a third control line by means of a first triplet of sample-and-hold circuits;
the fourth triplet of diodes is linked both to said first control column, said second control column and said third control column and to said second control line and said third control line by means of a second triplet of sample-and-hold circuits.

7. The display according to claim 6, wherein each sample-and-hold circuit is controlled by the third line and by one of the three control columns.

8. The display according to claim 1, wherein the area of the placement surface of the electronic component is about 300 microns by 300 microns.

9. The display according to claim 2, wherein the area of the placement surface of the electronic component is about 300 microns by 600 microns.

10. The display according to claim 3, wherein the area of the placement surface of the electronic component is about 600 microns by 600 microns.

11. A process for producing a display according to claim 1, wherein it includes a step of bonding the electronic components to bonding pads, the adhesive being conductive, isotropic and of solder paste-type.

12. The process for producing a display according to claim 1, wherein it includes a step of bonding the electronic components by means of an anisotropic conductive film-type bonding film, the adhesive being anisotropic, composed of an insulating medium including conductive microbeads.
